(19) United States
(12) Patent Application Publication
(10) Pub. No.: US 2025/0239320 A1
(43) Pub. Date: Jul. 24, 2025

(54) ERROR CORRECTION DISABLEMENT BY A MEMORY SYSTEM

(71) Applicant: Micron Technology, Inc., Boise, ID (US)

(72) Inventors: Marco Sforzin, Cernusco Sul Naviglio (MI) (IT); Antonino Caprì, Bergamo (IT); Graziano Mirichigni, Vimercate (MB) (IT); Nicola Corna, Gorle (BG) (IT)

(21) Appl. No.: 18/776,867

(22) Filed: Jul. 18, 2024

Related U.S. Application Data
(60) Provisional application No. 63/623,653, filed on Jan. 22, 2024.

(51) Int. Cl. G11C 29/42

(52) U.S. Cl. CPC G11C 29/42

(57) ABSTRACT

Methods, systems, and devices for error correction disablement by a memory system are described. The method may include a memory system reading, at a first time, data from one or more memory cells of a memory device and disabling a first error correction capability based on the data comprising one or more errors of a first type. Further, the method may include the memory system reading, at a second time, the data and transmitting the data to a host device based on the data not comprising the one or more errors of the first type.

### CROSS REFERENCE

The present application for patent claims the benefit of and priority to U.S. Patent Application No. 63/623,653 by Sforzin et al., entitled “ERROR CORRECTION DISABLEMENT BY A MEMORY SYSTEM,” filed Jan. 22, 2024, which is assigned to the assignee hereof, and which is expressly incorporated by reference in its entirety herein.

### TECHNICAL FIELD

The following relates to one or more systems for memory, including error correction disablement by a memory system.

### BACKGROUND

Memory devices are used to store information in devices such as computers, user devices, wireless communication devices, cameras, digital displays, and others. Information is stored by programming memory cells within a memory device to various states. For example, binary memory cells may be programmed to one of two supported states, often denoted by a logic 1 or a logic 0. In some examples, a single memory cell may support more than two states, any one of which may be stored by the memory cell. To store information, a memory device may write (e.g., program, set, assign) states to the memory cells. To access stored information, a memory device may read (e.g., sense, detect, retrieve, determine) states from the memory cells.

### BRIEF DESCRIPTION OF THE DRAWINGS

FIG. 1 shows an example of a system that supports error correction disablement by a memory system in accordance with examples as disclosed herein.

FIG. 2 shows an example of a flow diagram that supports error correction disablement by a memory system in accordance with examples as disclosed herein.

FIG. 3 shows a block diagram of a memory system that supports error correction disablement by a memory system in accordance with examples as disclosed herein.

FIGS. 4 and 5 show flowcharts illustrating a method or methods that support error correction disablement by a memory system in accordance with examples as disclosed herein.

### DETAILED DESCRIPTION

A memory system may be configured with a first error correction capability. In some examples, the first error correction capability may include an on-die error correction code (ECC). The memory system may perform on-die ECC to detect and potentially correct errors at a memory array of the memory system. For example, a memory device may receive a read command to access data at the memory array of the memory device. Based on or in response to the read command, the memory device may read the data from the memory array and perform on-die ECC on the data to detect and potentially correct errors in the data prior to sending the data to the host system. During on-die ECC, the memory device may determine if the data contains no errors, one or more errors of a first type (e.g., an uncorrectable error), or a one or more errors of a second type (e.g., a correctable error).

In addition to the first error correction capability, the memory system may also be configured with a second error correction capability. An example of the second error correction capability may include Reed-Solomon (RS) error correction. In some examples, the memory system may implement RS error correction in combination with on-die ECC. For example, one or more memory devices may receive a read command to read data from a respective memory array. In response to the read command, each memory device of the one or more memory devices may retrieve the data from their respective memory array and perform on-die ECC. Upon performing the on-die ECC, the one or more memory devices may transmit the data to a memory controller of the memory system for RS error correction. During RS error correction, the memory controller may determine if the data contains no errors, one or more errors of a first type (e.g., an uncorrectable error), or a one or more errors of a second type (e.g., a correctable error).

However, in some examples, the first error correction capability and the second error correction capability may not work together efficiently. For example, upon performing the first error correction capability (e.g., on-die ECC), a memory device may unintentionally introduce additional errors into the data and send the data with the additional errors to the memory controller for RS error decoding. The memory controller may be unable to correct the errors in the data, as well as the additional errors introduced by the ECC using RS error decoding, which may result in an uncorrectable error in the data. Alternatively, if the first error correction capability did not introduce the additional errors, the memory controller may have the capability to correct the data using RS error decoding. Accordingly, a memory system configured to disable on-die ECC to prevent or otherwise mitigate errors from being introduced into data (e.g., due to ECC) may be desirable.

As described herein, a memory system may be configured to disable an error correction capability. In some examples, at a first time, the memory system may read data from one or more memory cells of a memory device and determine that the data includes one or more errors of a first type (e.g., uncorrectable errors). For example, the system may fail to correct the one or more errors using the first error correction capability (on-die ECC) or the second error correction capability (RS error decoding) and may determine that the data includes an uncorrectable error. Upon determining the data includes the one or more errors of the first type, the memory system may disable the first error correction capability.

At a second time and while the first error correction capability is disabled, the memory system may read (or reread) the data from the one or more memory cells of the memory device and may determine that the data does not include the one or more errors of a second type, but instead includes one or more errors of a second type (e.g., a correctable error). For example, with the first error capability disabled, the memory system may solely perform the second error correction capability (or RS error decoding) on the data. Using the second error correction capability, the memory system may determine that the data includes one or more errors of the second type (e.g., a correctable error) and may correct the one or more errors in the data before transmitting the data to a host system. The methods as described herein may allow the memory system to selectively disable a first error correction capability of the memory system which, in some scenarios, may reduce uncorrectable errors in the data. Reducing or otherwise mitigating the occurrence of such uncorrectable errors in data may improve the system's capability to identify and correct errors, which may improve the overall performance of the memory system.

In addition to applicability in memory systems as described herein, techniques for error correction disablement by a memory system may be generally implemented to support increased connectivity of electronic systems. As the use of systems relying on interconnected electronic devices increases, the connectivity of these electronic devices becomes an increasingly relevant factor for the operations of the system. For example, delays associated with signals communicated between devices may become increasingly relevant as critical systems come to rely more on connectivity, as a system uses larger quantities of interconnected devices, or if the quantity and the complexity of signals communicated between devices increases. Implementing the techniques described herein may support techniques for increased connectivity in electronic systems by improving data transfer between devices, among other benefits.

Features of the disclosure are illustrated and described in the context of systems and architectures. Features of the disclosure are further illustrated and described in the context of a flow diagram and flowcharts.

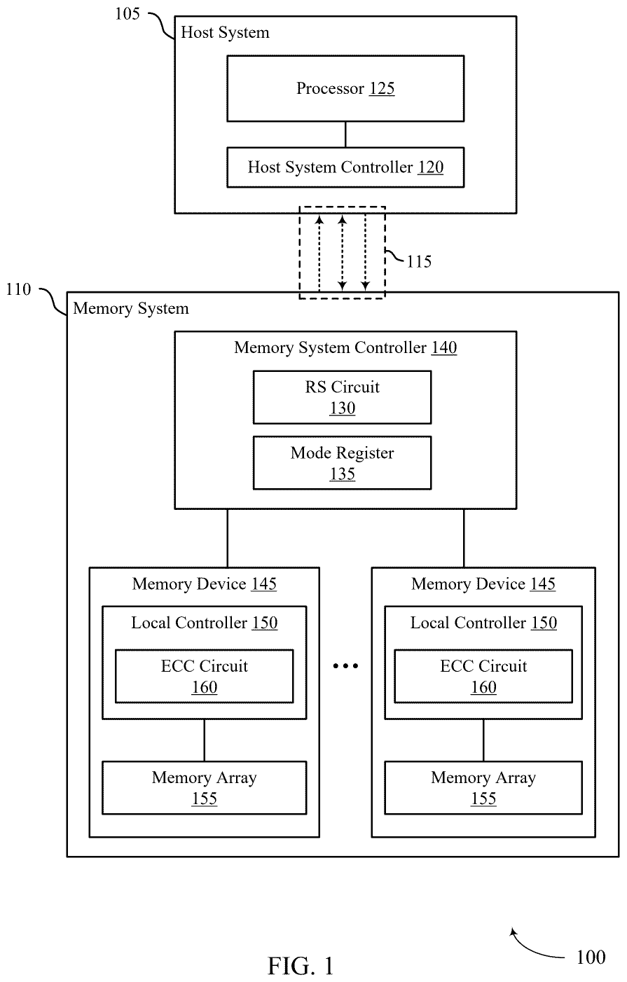

FIG. 1 illustrates an example of a system 100 that supports error correction disablement by a memory system in accordance with examples as disclosed herein. The system 100 may include portions of an electronic device, such as a computing device, a mobile computing device, a wireless communications device, a graphics processing device, a vehicle, a smartphone, a wearable device, an internet-connected device, a vehicle controller, a system on a chip (SoC), or other stationary or portable electronic system, among other examples. The system 100 includes a host system 105, a memory system 110, and one or more channels 115 coupling the host system 105 with the memory system 110 (e.g., to support a communicative coupling). The system 100 may include any quantity of one or more memory systems 110 coupled with the host system 105.

The host system 105 may include one or more components (e.g., circuitry, processing circuitry, one or more processing components) that use memory to execute processes, any one or more of which may be referred to as or be included in a processor 125. The processor 125 may include at least one of one or more processing elements that may be co-located or distributed, including a general-purpose processor, a digital signal processor (DSP), an application-specific integrated circuit (ASIC), a field-programmable gate array (FPGA) or other programmable logic device, a controller, discrete gate or transistor logic, one or more discrete hardware components, or a combination thereof. The processor 125 may be an example of a central processing unit (CPU), a graphics processing unit (GPU), a general-purpose GPU (GPGPU), or an SoC or a component thereof, among other examples.

The host system 105 may also include at least one of one or more components (e.g., circuitry, logic, instructions) that implement the functions of an external memory controller (e.g., a host system memory controller), which may be referred to as or be included in a host system controller 120. For example, a host system controller 120 may issue commands or other signaling for operating the memory system 110, such as write commands, read commands, configuration signaling or other operational signaling. In some examples, the host system controller 120, or associated functions described herein, may be implemented by or be part of the processor 125. For example, a host system controller 120 may be hardware, instructions (e.g., software, firmware), or some combination thereof implemented by the processor 125 or other component of the host system 105. In various examples, a host system 105 or a host system controller 120 may be referred to as a host.

The memory system 110 provides physical memory locations (e.g., addresses) that may be used or referenced by the system 100. The memory system 110 may include a memory system controller 140 and one or more memory devices 145 (e.g., memory packages, memory dies, memory chips) operable to store data. The memory system 110 may be configurable for operations with different types of host systems 105, and may respond to commands from the host system 105 (e.g., from a host system controller 120). For example, the memory system 110 (e.g., a memory system controller 140) may receive a write command indicating that the memory system 110 is to store data received from the host system 105, or receive a read command indicating that the memory system 110 is to provide data stored in a memory device 145 to the host system 105, or receive a refresh command indicating that the memory system 110 is to refresh data stored in a memory device 145, among other types of commands and operations.

A memory system controller 140 may include at least one of one or more components (e.g., circuitry, logic, instructions) operable to control operations of the memory system 110. A memory system controller 140 may include hardware or instructions that support the memory system 110 performing various operations, and may be operable to receive, transmit, or respond to commands, data, or control information related to operations of the memory system 110. A memory system controller 140 may be operable to communicate with one or more of a host system controller 120, one or more memory devices 145, or a processor 125. In some examples, a memory system controller 140 may control operations of the memory system 110 in cooperation with the host system controller 120, a local controller 150 of a memory device 145, or any combination thereof. Although the example of memory system controller 140 is illustrated as a separate component of the memory system 110, in some examples, aspects of the functionality of the memory system 110 may be implemented by a processor 125, a host system controller 120, at least one of one or more local controllers 150, or any combination thereof.

Each memory device 145 may include a local controller 150 and one or more memory arrays 155. A memory array 155 may be a collection of memory cells (e.g., a two-dimensional array, a three-dimensional array), with each memory cell being operable to store data (e.g., as one or more stored bits). Each memory array 155 may include memory cells of various architectures, such as random access memory (RAM) cells, dynamic RAM (DRAM) cells, synchronous dynamic RAM (SDRAM) cells, static RAM (SRAM) cells, ferroelectric RAM (FeRAM) cells, magnetic RAM (MRAM) cells, resistive RAM (RRAM) cells, phase change memory (PCM) cells, chalcogenide memory cells, not-or (NOR) memory cells, and not-and (NAND) memory cells, or any combination thereof.

A local controller 150 may include at least one of one or more components (e.g., circuitry, logic, instructions) operable to control operations of a memory device 145. In some examples, a local controller 150 may be operable to communicate (e.g., receive or transmit data or commands or both) with a memory system controller 140. In some examples, a memory system 110 may not include a memory system controller 140, and a local controller 150 or a host system controller 120 may perform functions of a memory system controller 140 described herein. In some examples, a local controller 150, or a memory system controller 140, or both may include decoding components operable for accessing addresses of a memory array 155, sense components for sensing states of memory cells of a memory array 155, write components for writing states to memory cells of a memory array 155, or various other components operable for supporting described operations of a memory system 110.

A host system 105 (e.g., a host system controller 120) and a memory system 110 (e.g., a memory system controller 140) may communicate information (e.g., data, commands, control information, configuration information) using one or more channels 115. Each channel 115 may be an example of a transmission medium that carries information, and each channel 115 may include one or more signal paths (e.g., a transmission medium, an electrical conductor, a conductive path) between terminals (e.g., nodes, pins, contacts) associated with the components of the system 100. A terminal may be an example of a conductive input or output point of a device of the system 100, and a terminal may be operable as part of a channel 115. To support communications over channels 115, a host system 105 (e.g., a host system controller 120) and a memory system 110 (e.g., a memory system controller 140) may include receivers (e.g., latches) for receiving signals, transmitters (e.g., drivers) for transmitting signals, decoders for decoding or demodulating received signals, or encoders for encoding or modulating signals to be transmitted, among other components that support signaling over channels 115, which may be included in a respective interface portion of the respective system.

A channel 115 is dedicated to communicating one or more types of information, and channels 115 may include unidirectional channels, bidirectional channels, or both. For example, the channels 115 may include one or more command/address channels, one or more clock signal channels, one or more data channels, among other channels or combinations thereof. In some examples, a channel 115 may be configured to provide power from one system to another (e.g., from the host system 105 to the memory system 110, in accordance with a regulated voltage). In some examples, at least a subset of channels 115 may be configured in accordance with a protocol (e.g., a logical protocol, a communications protocol, an operational protocol, an industry standard), which may support configured operations of and interactions between a host system 105 and a memory system 110.

A command/address channel (e.g., a CA channel) may be operable to communicate commands between the host system 105 and the memory system 110, including control information associated with the commands (e.g., address information, configuration information). Commands carried by a command/address channel may include a write command with an address for data to be written to the memory system 110 or a read command with an address of data to be read from the memory system 110.

A clock signal channel may be operable to communicate one or more clock signals between the host system 105 and the memory system 110. Clock signals may oscillate between a high state and a low state, and may support coordination (e.g., in time) between operations of the host system 105 and the memory system 110. In some examples, a clock signal may provide a timing reference for operations of the memory system 110. A clock signal may be referred to as a control clock signal, a command clock signal, or a system clock signal. A system clock signal may be generated by a system clock, which may include one or more hardware components (e.g., oscillators, crystals, logic gates, transistors).

A data channel (e.g., a DQ channel) may be operable to communicate (e.g., bidirectionally) information (e.g., data, control information) between the host system 105 and the memory system 110. For example, a data channel may communicate information from the host system 105 to be written to the memory system 110, or information read from the memory system 110 to the host system 105. In some examples, channels 115 may include one or more error detection code (EDC) channels. An EDC channel may be operable to communicate error detection signals, such as checksums or parity bits, which may accompany information conveyed over a data channel.

In some examples, each memory device 145 of the memory system 110 may include an ECC circuit 160. Using the ECC circuit 160, a memory device 145 may perform on-die ECC. On-die ECC may allow the memory device 145 to detect and correct errors present in the memory array 155 of the memory device 145. During a write operation, the ECC circuit 160 may generate a first set of parity bits corresponding to write data and may store the first set of parity bits along with the write data in the memory array 155. During a read operation, the memory device 145 may read the data from the memory array 155 and the ECC circuit 160 may check the read data for errors using the first set of parity bits. For example, the ECC circuit 160 may generate a second set of parity bits based on the read data and may compare the second set of parity bits to the first set of parity bits. If the second set of parity bits match the first set of parity bits, the ECC circuit 160 may detect zero errors in the read data (e.g., the data may not include any errors) and the memory system 110 may send the read data to the host system 105.

Alternatively, if the first set of parity bits and the second set of parity bits do not match, the ECC circuit 160 may detect one or more errors in the read data. If only one error is detected (e.g., a single bit error (SBE)) the ECC circuit 160 may implement single error correction (SEC) code (e.g., Hamming code) to correct the error and the memory device 145 may send the corrected read data to the host system 105. However, if the ECC circuit 160 detects more than one error in the data (e.g., multi-bit error (MBE)), the ECC circuit 160 may be unable to correct the errors in the read data and, in some scenarios, may send a message to host system 105 indicating that the memory device 145 was unable to correct the errors in the read data. Errors that the ECC circuit 160 is able to correct may be referred to as correctable errors and errors that the ECC circuit 160 is unable to correct may be referred to as uncorrectable errors.

In addition to on-die ECC, the memory system 110 may implement RS code for error correction using an RS circuit 130. RS code may be a block-based error correcting code. In some examples, to increase speed, the memory system 110 may read data from multiple memory devices 145 in parallel. For example, the memory system 110 may read a first portion of data from a first memory array 155 of a first memory device 145 and a second portion of the data from a second memory array 155 of a second memory device 145 in parallel. After on-die ECC is performed on the respective portions of the data, the memory devices 145 may send the data to the memory system controller 140. At the memory system controller 140, the RS circuit 130 may detect and potentially correct errors in the data using RS code.

However, in some examples, the ECC circuits 160 may be unable to correct one or more errors in the data stored at the memory arrays 155. For example, the ECC circuit 160 may detect an SBE and fail to correct the SBE. In addition to failing to correct the SBE, the ECC circuit 160 may potentially introduce additional errors into the data resulting in an uncorrectable error (e.g., an MBE). Thus, the RS circuit 130 may receive data with the additional errors introduced by the ECC circuits 160. In some examples, the additional errors may contaminate one or more symbols of the RS codeword (e.g., data or parity symbols) and the RS circuit 130 may be unable to correct the errors present in the read data. Further, even if only one ECC circuit 160 of the memory devices 145 introduces the additional error(s) into a portion of the read data, the entirety of the data may be affected because the RS circuit 130 collectively analyzes the data read from all the memory devices 145 involved in the parallel read operation. Without on-die ECC, the read data may not contain the additional errors (e.g., the errors introduced by the ECC circuit(s) 160) which may allow the RS circuit 130 to correct the original errors in the read data.

Therefore, in some scenarios (e.g., while utilizing RS circuit 130 or while the memory system 110 is in a testing mode), it may be beneficial for the memory system 110 or the host system 105 to dynamically disable on-die ECC. As shown in FIG. 1, the memory system controller 140 may include a mode register 135 (e.g., MR50 or another mode register) that is configured to store a set of bits that indicate one or more operational states of the memory system 110. In some examples, one or more bits of the set of bits may relate to on-die ECC operation for the memory system 110. For example, a first bit stored in the mode register 135 may indicate whether a disablement of on-die ECC is supported by the memory system 110. As an example, a bit value of 1 in a first position of the mode register 135 may indicate that disablement of on-die ECC (or DiSEC) is supported, whereas a bit value of 0 may indicate that disablement of on-die ECC is not supported. In some examples, the bit value of the first bit (e.g., in the first position) may be programmed during a manufacturing stage of the memory system 110.

Additionally, or alternatively, a second bit stored in a second position of the mode register 135 may indicate whether disablement of on-die ECC is enabled for the memory system 110. As an example, a bit value of 1 may indicate that disablement of on-die ECC (or disablement of single error correction (DiSEC or DS)) is enabled, whereas a bit value of 0 may indicate that disablement of on-die ECC is not enabled. In some examples, the bit value of the second bit may be dynamically programmed using a mode register write (MRW) command. Further, in some examples, the second bit may be protected by a key (e.g., secret key or guard key). For example, the host system 110 may issue a specific sequence of commands (e.g., guard key) which enables the memory system 110 to change or update the second bit in the mode register 135. If the specific sequence of commands is not issued by the host system 105, the second bit is maintained.

Tables 1 and 2 show an example of the set of bits stored in the mode register 135. In the example of Tables 1 and 2, the mode register 135 may store 8 bits which are represented by OP0, OP1, OP2, OP3, OP4, OP5, OP6, and OP7 in Tables 1 and 2. OP1 through OP5 may relate to a cyclic redundancy check (CRC) operation at the memory system 110 and OP6 and OP7 relate to on-die ECC operation. Specifically, OP[6] may be an example of the first bit (e.g., a DiSEC support bit) in the first position and OP[7] may be an example of the second bit (e.g., a DiSEC enablement bit) in the second position. If the bit value of the first bit (e.g., OP[6]) indicates that disablement of on-die ECC is supported (e.g., is set to 1) and the bit value of the second bit (e.g., OP[7]) indicates that disablement of on-die ECC is enabled (e.g., is set to 1), on-die ECC may be disabled at the memory system 110. The contents of Tables 1 and 2 are merely exemplary and it should be understood that the bits stored in the mode register 135 (e.g., OP1 through OP5) may represent other feature (e.g., different from the features related to CRC operation). Further, the order of the bits in the mode register 135 can be different from what is represented in Tables 1 and 2.

TABLE 1

| OP7 | OP6 | OP5 | OP4 | OP3 | OP2 | OP1 | OP0 |
|---|---|---|---|---|---|---|---|
| DiSEC | DiSEC | Write | Write | Write | Write | Write | Read |
| Enable | Support | CRC | CRC | CRC | CRC | CRC | CRC |
| | | Auto- | Auto- | Error | Enable | Enable | Enable |
| | | Disable | Disable | Status | Upper | Lower | |
| | | Status | Enable | | Nibble | Nibble | |

TABLE 2

| Function | Type | OP | Description/Data |
|---|---|---|---|
| Read CRC Enable | R/W | OP[0] | 0 = disable (default), |
| | | | 1 = enable |
| Write CRC Enable Lower | R/W | OP[1] | 0 = disable (default), |
| Nibble | | | 1 = enable |
| Write CRC Enable Upper | R/W | OP[2] | 0 = disable (default), |
| Nibble | | | 1 = enable |
| Write CRC Error Status | R/W | OP[3] | 0 = disable (default), |
| | | | 1 = enable |
| Write CRC Auto-Disable | R/W | OP[4] | 0 = disable (default), |
| Enable | | | 1 = enable |
| Write CRC Auto-Disable Status | R/W | OP[5] | 0 = disable (default), |
| | | | 1 = enable |
| DiSEC Support | R | OP[6] | 0 = not supported, |
| | | | 1 = supported |
| DiSEC Enable | R/W | OP[7] | 0 = disable (default), |
| | | | 1 = enable |

In some examples, the memory system 110 may disable on-die ECC in response to a trigger. An example of the trigger may be a command (e.g., a write command, a write auto precharge command, a read command, or a read auto precharge command) received from the host system 105. As one example, the host system 105 may transmit a command to access data from the memory array 155 of the memory device 145. In addition to indicating a location of the data to be accessed, the command may additionally indicate whether the memory device 145 is to perform the access operation without on-die ECC.

If the command indicates to disable on-die ECC, the memory device 145 may perform the access operation without implementing the ECC circuit 160 (or without on-die ECC). Moreover, in response to the command and/or prior to performing the access operation with on-die ECC disabled, the memory system 110 may perform a mode register read (MRR) on the mode register 135 to ensure that disablement of on-die ECC is enabled or supported by the memory system 110. If on-die ECC is not enabled or supported by the memory system 110 (e.g., as indicated in the mode register 135), the memory system 110 may perform the access operation with on-die ECC enabled even if the command indicates otherwise. In another example, the command may indicate to enable on-die ECC. In such cases, the memory device 145 may perform the access operation with the ECC circuit 160 (or with on-die ECC).

In some examples, upon receiving the command to disable on-die ECC, the memory system 110 may disable on-die ECC for the duration of an operation (e.g., a read operation or a write operation) indicated by the command. After the duration, the memory system 110 may reactivate on-die ECC and on-die ECC may remain active until otherwise indicated (e.g., deactivated via another command or trigger). Alternatively, after the duration, on-die ECC may remain deactivated until otherwise indicated (e.g., activated via another command or trigger).

Table 3 illustrates how the indication may be incorporated into a command, such as a read command. To signal the command to the memory system 110, the host system 105 may apply a respective voltage to each pin of a set of pins (e.g., connecting the host system 105 and the memory system 110). The set of pins may include a chip select (CS) pin and multiple CA pins (e.g., CAO through CA13). At least one pin of the set of pins may correspond to on-die ECC disablement (DiSEC or DS). For example, as shown in Table 3, CA9 may correspond to on-die ECC disablement (DiSEC or DS). To indicate that on-die ECC is disabled for a read operation specified by the read command, the host system 105 may set the CA9 pin to HIGH (e.g., voltage output of the pin is above a threshold). Alternatively, to indicate that on-die ECC is enabled for the read operation specified by the read command, the host system 105 may set the CA9 pin to LOW (e.g., voltage output of the pin is below a threshold). The contents of Table 3 is merely exemplary and it should be understood that the on-die ECC disablement may correspond to a different pin than what is illustrated in Table 3 (e.g., different from CA9).

TABLE 3
Command Truth Table.

| | | | CA Pins | | | | | | | |
|---|---|---|---|---|---|---|---|---|---|---|
| Function | Abv. | CS | CA0 | CA1 | . . . | CA9 | CA10 | C11 | CA12 | CA13 |
| Read | RD | L | H | L | . . . | BG1 | BG2 | CID0 | CID1 | CID2 |
| | | H | C2 | C3 | . . . | DS | H | V | V | CID3 |

As described herein, a memory system 110 may dynamically disable on-die ECC. Disabling the on-die ECC may be beneficial in multiple situations. For example, the memory system 110 may disable on-die ECC while performing a read operation on multiple memory devices 145 in parallel to avoid uncorrectable errors at the RS circuit 130. Further, the memory system 110 may disable on-die ECC while the memory system 110 is operating in a test mode such that the memory system 110 may evaluate aspects of the faulty bits (e.g., their location within the memory arrays 155).

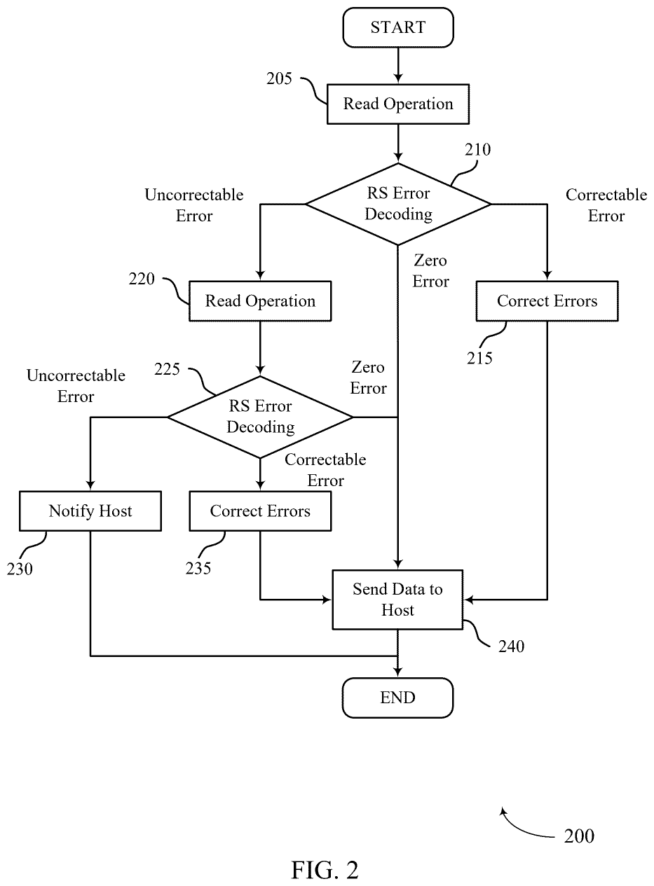

FIG. 2 shows an example of a flow diagram 200 that supports error correction disablement by a memory system in accordance with examples as disclosed herein. In some examples, the flow diagram 200 may be implemented by aspects of the memory system 110 as described in FIG. 1. For example, the flow diagram 200 may be implemented by one or more of the memory system controller 140, the RS circuit 130, the memory device 145, the local controller 150, or the ECC circuit 160.

At 205, a memory system may perform a first read operation. During the first read operation, one or more memory devices of the memory system (or local controllers) may retrieve read data stored at one or more memory arrays. Upon retrieving the read data from the one or more memory arrays, one or more ECC circuits may perform on-die ECC (or a first error correction capability) on the read data. In some examples, each memory device of the one or more memory devices may include an ECC circuit. In such examples, an ECC circuit of each of the respective memory devices may perform on-die ECC on a respective portion of the data. Alternatively, the memory system may include a single ECC circuit corresponding to multiple memory devices. In such examples, the single ECC circuit may perform on-die ECC on the data. Performing on-die ECC may include applying SEC code to the read data to detect (and potentially correct) single bit errors in the read data. After performing on-die ECC, the one or more memory devices may transmit the read data to an RS circuit of a memory system controller of the memory system and proceed to 210.

At 210, the memory system controller of the memory system may perform RS error decoding (e.g., a second error correction capability) on the read data using an RS circuit and determine whether there are errors in the read data. In some examples, the RS circuit may detect zero errors in the read data and may proceed to 240.

At 240, the memory system may transmit the read data to the host system.

Alternatively, at 210, the RS circuit may detect a correctable error (or an error of a second type) in the read data and may proceed to 215. A correctable error may include an error that is correctable by the RS circuit. At 215, the RS circuit may correct the correctable error in the read data and may proceed to 240.

Alternatively, at 210, the RS circuit may detect an uncorrectable error (or an error of a first type) in the read data and may proceed to 220. An uncorrectable error may include an error that is uncorrectable by the RS circuit. An uncorrectable error may occur if the ECC circuit was unable to correct errors in the read data. In some examples, the ECC circuit may attempt to correct the uncorrectable error and fail, resulting in additional errors in the read data.

At 220, the one or more memory devices may perform a second read operation to read (or reread) the read data from the one or more memory arrays. In some examples, prior to performing the second read operation, the memory system may receive an indication to disable on-die ECC. For example, the memory system may receive a command (e.g., a read command for the second read operation or a write command) that includes an indication to disable on-die ECC. In response to the indication, the memory system may perform the second read operation without performing on-die ECC. That is, the one or more memory devices may retrieve the read data from the one or more memory arrays and may send the read data directly to the memory system controller for RS error decoding at 225, thus bypassing the ECC circuits of the one or more memory devices.

At 225, the memory system controller of the memory system may perform RS error decoding on the read data using the RS circuit and determine whether there are errors in the data. In some examples, the RS circuit may detect zero errors in the read data and may proceed to 240.

Alternatively, at 225, the RS circuit may detect a correctable error in the read data and may proceed to 235. A correctable error may include an error that is correctable by the RS circuit, such as a single-bit error. At 235, the RS circuit may correct the correctable error in the read data and may proceed to 240.

Alternatively, at 225, the RS circuit may detect an uncorrectable error in the read data and proceed to 220. An uncorrectable error may include an error that is uncorrectable by the RS circuit, such as a multi-bit error. Upon detecting the uncorrectable error, the memory system may proceed to 230.

At 230, the memory system may transmit a message to the host system indicating that the memory system encountered an uncorrectable error while performing the second read operation. Using the methods as described herein may allow the memory system to dynamically disable on-die ECC which may decrease a number of uncorrectable errors in the data thereby allowing other circuitry (e.g., RS circuits) of the memory system to correct the errors.

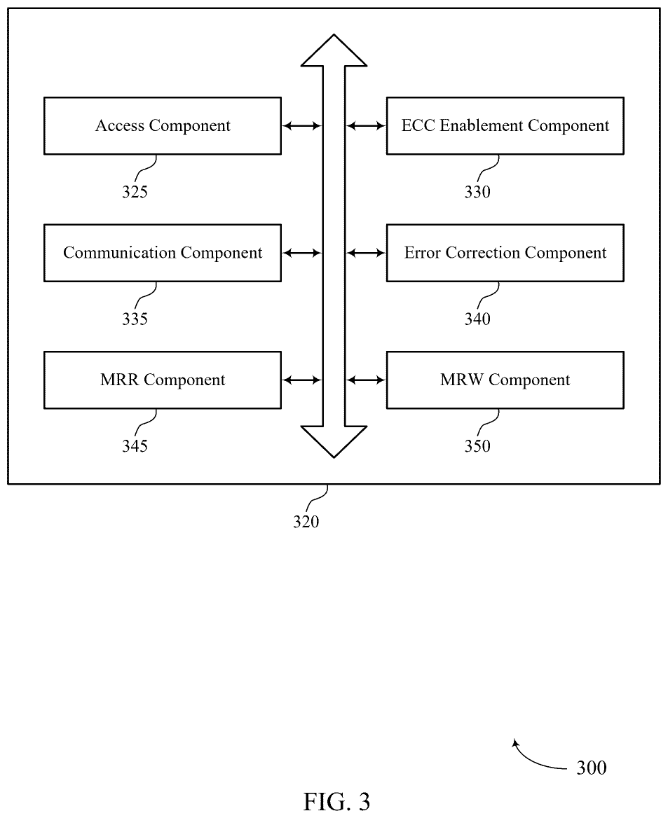

FIG. 3 shows a block diagram 300 of a memory system 320 that supports error correction disablement by a memory system in accordance with examples as disclosed herein. The memory system 320 may be an example of aspects of a memory system as described with reference to FIGS. 1 through 2. The memory system 320, or various components thereof, may be an example of means for performing various aspects of error correction disablement by a memory system as described herein. For example, the memory system 320 may include an access component 325, an ECC enablement component 330, a communication component 335, an error correction component 340, an MRR component 345, an MRW component 350, or any combination thereof. Each of these components, or components of subcomponents thereof (e.g., one or more processors, one or more memories), may communicate, directly or indirectly, with one another (e.g., via one or more buses).

The access component 325 may be configured as or otherwise support a means for reading, at a first time, data from one or more memory cells of a memory device. The ECC enablement component 330 may be configured as or otherwise support a means for disabling a first error correction capability of the memory system based on determining that data read from one or more memory cells of the memory system includes one or more errors of a first type. In some examples, the access component 325 may be configured as or otherwise support a means for reading, at a second time, the data from the one or more memory cells of the memory device. The communication component 335 may be configured as or otherwise support a means for transmitting the data to a host device based on determining that the data does not include the one or more errors of the first type based on reading the data from the one or more memory cells of the memory system for a second time.

In some examples, to support determining that the data read from the one or more memory cells of the memory system includes one or more errors of the first type, the error correction component 340 may be configured as or otherwise support a means for failing to correct at least one error in the data using a second error correction capability of the memory system. In some examples, the second error correction capability of the memory system includes an RS error correction code.

In some examples, the access component 325 may be configured as or otherwise support a means for reading, at a third time, second data from one or more second memory cells of the memory system. In some examples, the error correction component 340 may be configured as or otherwise support a means for correcting the one or more errors in the second data using a second error correction capability of the memory system based on determining that the second data includes one or more errors of a second type. In some examples, the communication component 335 may be configured as or otherwise support a means for transmitting the second data to the host device based on correcting the one or more errors in the second data using the second error correction capability of the memory system.

In some examples, the one or more errors of the first type include an uncorrectable error (UE). In some examples, the one or more errors of the second type include a correctable error (CE).

In some examples, the access component 325 may be configured as or otherwise support a means for reading third data from one or more third memory cells of the memory system. In some examples, the error correction component 340 may be configured as or otherwise support a means for determining that the third data includes zero errors based on reading the third data from the one or more third memory cells of the memory system. In some examples, the communication component 335 may be configured as or otherwise support a means for transmitting the third data to the host device based on determining that the third data includes zero errors.

In some examples, the error correction component 340 may be configured as or otherwise support a means for determining that the data includes one or more errors of a second type based on determining that the data does not include the one or more errors of the first type. In some examples, the error correction component 340 may be configured as or otherwise support a means for correcting the one or more errors of the second type using a second type of error correction capability of the memory system based on determining that the data includes the one or more errors of the second type, where transmitting the data to the host device is based on correcting the one or more errors of the second type.

In some examples, to support determining that the data does not include the one or more errors of the first type, the error correction component 340 may be configured as or otherwise support a means for determining that the data includes zero errors, where transmitting the data to the host device is based on determining that the data includes zero errors.

In some examples, the MRR component 345 may be configured as or otherwise support a means for reading a first bit value from a mode register of the memory system, where the first bit value indicates that the first error correction capability of the memory system is configured to be disabled, where disabling the first error correction capability of the memory system is based on reading the first bit value from the mode register of the memory system.

In some examples, the MRW component 350 may be configured as or otherwise support a means for receiving, from the host device, a command including an indication to write a second bit value to a mode register of the memory system based on determining that the data read from the one or more memory cells of the memory system includes the one or more errors of the first type. In some examples, the MRW component 350 may be configured as or otherwise support a means for writing the second bit value to a mode register of the memory system based on receiving the command, where disabling the first error correction capability of the memory system is based on writing the second bit value to the mode register.

In some examples, the MRR component 345 may be configured as or otherwise support a means for receiving, from the host device, a secret key, where writing the second bit value to the mode register of the memory system is based on the secret key.

In some examples, the ECC enablement component 330 may be configured as or otherwise support a means for receiving, from the host device and based on determining that the data includes the one or more errors of the first type, a command to reread the data from the one or more memory cells of the memory system, where the command includes an indication to disable the first error correction capability of the memory system.

In some examples, the command includes a write command, a write auto precharge command, a read command, or a read auto precharge command.

In some examples, the ECC enablement component 330 may be configured as or otherwise support a means for enabling the first error correction capability of the memory system based on transmitting the data to the host device. In some examples, the first error correction capability includes an on-die ECC.

In some examples, the error correction component 340 may be configured as or otherwise support a means for determining that the data read from the one or more memory cells of the memory system at the first time includes the one or more errors of the first type. In some examples, the error correction component 340 may be configured as or otherwise support a means for determining that the data read from the one or more memory cells of the memory system at the second time does not include the one or more errors of the first type.

In some examples, the access component 325 may be configured as or otherwise support a means for reading, at a fourth time, third data from one or more third memory cells of the memory device. In some examples, the access component 325 may be configured as or otherwise support a means for rereading, at a fifth time, the third data from the one or more third memory cells of the memory device. In some examples, the error correction component 340 may be configured as or otherwise support a means for transmitting an indication to the host device based on determining that the third data includes one or more errors of the first type based on rereading the third data from the one or more third memory cells of the memory system.

In some examples, the described functionality of the memory system 320, or various components thereof, may be supported by or may refer to at least a portion of at least one processor, where such at least one processor may include one or more processing elements (e.g., a controller, a microprocessor, a microcontroller, a digital signal processor, a state machine, discrete gate logic, discrete transistor logic, discrete hardware components, or any combination of one or more of such elements). In some examples, the described functionality of the memory system 320, or various components thereof, may be implemented at least in part by instructions (e.g., stored in memory, non-transitory computer-readable medium) executable by such at least one processor.

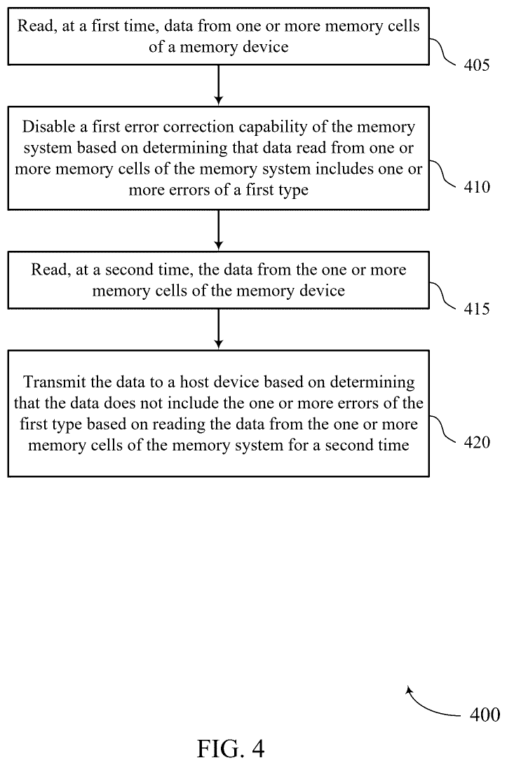

FIG. 4 shows a flowchart illustrating a method 400 that supports error correction disablement by a memory system in accordance with examples as disclosed herein. The operations of method 400 may be implemented by a memory system or its components as described herein. For example, the operations of method 400 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 405, the method may include reading, at a first time, data from one or more memory cells of a memory device. The operations of 405 may be performed in accordance with examples as disclosed herein. For example, the memory system may include an access component 325 that reads, at the first time, the data from the one or more memory cells of the memory device (e.g., the memory device 145 of FIG. 1).

At 410, the method may include disabling a first error correction capability of the memory system based on determining that data read from one or more memory cells of the memory system includes one or more errors of a first type. The operations of 410 may be performed in accordance with examples as disclosed herein. For example, the memory system may include an ECC enablement component 330 that disables a first error correction capability (e.g., ECC circuit 160 of FIG. 1) of the memory system based on determining that the data read from the one or more memory cells of the memory system includes one or more errors of a first type.

At 415, the method may include reading, at a second time, the data from the one or more memory cells of the memory device. The operations of 415 may be performed in accordance with examples as disclosed herein. For example, the memory system may include an access component 325 that reads, at the second time, the data from the one or more memory cells of the memory device (e.g., the memory device 145 of FIG. 1).

At 420, the method may include transmitting the data to a host device based on determining that the data does not include the one or more errors of the first type based on reading the data from the one or more memory cells of the memory system for a second time. The operations of 420 may be performed in accordance with examples as disclosed herein. For example, the memory system may include a communication component 335 that transmits the data to the host device (e.g., the host system 105 of FIG. 1) based on determining that the data does not include the one or more errors of the first type and based on reading the data from the one or more memory cells of the memory system for a second time.

In some examples, an apparatus as described herein may perform a method or methods, such as the method 400. The apparatus may include features, circuitry, logic, means, or instructions (e.g., a non-transitory computer-readable medium storing instructions executable by a processor), or any combination thereof for performing the following aspects of the present disclosure:

Aspect 1: A method, apparatus, or non-transitory computer-readable medium including operations, features, circuitry, logic, means, or instructions, or any combination thereof for reading, at a first time, data from one or more memory cells of a memory device; disabling a first error correction capability of the memory system based on determining that data read from one or more memory cells of the memory system includes one or more errors of a first type; reading, at a second time, the data from the one or more memory cells of the memory device; and transmitting the data to a host device based on determining that the data does not include the one or more errors of the first type based on reading the data from the one or more memory cells of the memory system for a second time.

Aspect 2: The method, apparatus, or non-transitory computer-readable medium of aspect 1, where determining that the data read from the one or more memory cells of the memory system includes one or more errors of the first type includes operations, features, circuitry, logic, means, or instructions, or any combination thereof for failing to correct at least one error in the data using a second error correction capability of the memory system.

Aspect 3: The method, apparatus, or non-transitory computer-readable medium of aspect 2, where the second error correction capability of the memory system includes an RS error correction code.

Aspect 4: The method, apparatus, or non-transitory computer-readable medium of any of aspects 1 through 3, further including operations, features, circuitry, logic, means, or instructions, or any combination thereof for reading, at a third time, second data from one or more second memory cells of the memory system; correcting the one or more errors in the second data using a second error correction capability of the memory system based on determining that the second data includes one or more errors of a second type; and transmitting the second data to the host device based on correcting the one or more errors in the second data using the second error correction capability of the memory system.

Aspect 5: The method, apparatus, or non-transitory computer-readable medium of aspect 4, where the one or more errors of the first type include an uncorrectable error (UE) and the one or more errors of the second type include a correctable error (CE).

Aspect 6: The method, apparatus, or non-transitory computer-readable medium of any of aspects 1 through 5, further including operations, features, circuitry, logic, means, or instructions, or any combination thereof for reading third data from one or more third memory cells of the memory system; determining that the third data includes zero errors based on reading the third data from the one or more third memory cells of the memory system; and transmitting the third data to the host device based on determining that the third data includes zero errors.

Aspect 7: The method, apparatus, or non-transitory computer-readable medium of any of aspects 1 through 6, further including operations, features, circuitry, logic, means, or instructions, or any combination thereof for determining that the data includes one or more errors of a second type based on determining that the data does not include the one or more errors of the first type and correcting the one or more errors of the second type using a second type of error correction capability of the memory system based on determining that the data includes the one or more errors of the second type, where transmitting the data to the host device is based on correcting the one or more errors of the second type.

Aspect 8: The method, apparatus, or non-transitory computer-readable medium of any of aspects 1 through 7, where determining that the data does not include the one or more errors of the first type includes operations, features, circuitry, logic, means, or instructions, or any combination thereof for determining that the data includes zero errors, where transmitting the data to the host device is based on determining that the data includes zero errors.

Aspect 9: The method, apparatus, or non-transitory computer-readable medium of any of aspects 1 through 8, further including operations, features, circuitry, logic, means, or instructions, or any combination thereof for reading a first bit value from a mode register of the memory system, where the first bit value indicates that the first error correction capability of the memory system is configured to be disabled, where disabling the first error correction capability of the memory system is based on reading the first bit value from the mode register of the memory system.

Aspect 10: The method, apparatus, or non-transitory computer-readable medium of any of aspects 1 through 9, further including operations, features, circuitry, logic, means, or instructions, or any combination thereof for receiving, from the host device, a command including an indication to write a second bit value to a mode register of the memory system based on determining that the data read from the one or more memory cells of the memory system includes the one or more errors of the first type and writing the second bit value to a mode register of the memory system based on receiving the command, where disabling the first error correction capability of the memory system is based on writing the second bit value to the mode register.

Aspect 11: The method, apparatus, or non-transitory computer-readable medium of aspect 10, further including operations, features, circuitry, logic, means, or instructions, or any combination thereof for receiving, from a host device, a secret key, where writing the second bit value to the mode register of the memory system is based on the secret key.

Aspect 12: The method, apparatus, or non-transitory computer-readable medium of any of aspects 1 through 11, further including operations, features, circuitry, logic, means, or instructions, or any combination thereof for receiving, from the host device and based on determining that the data includes the one or more errors of the first type, a command to reread the data from the one or more memory cells of the memory system, where the command includes an indication to disable the first error correction capability of the memory system.

Aspect 13: The method, apparatus, or non-transitory computer-readable medium of aspect 12, where the command includes a write command, a write auto precharge command, a read command, or a read auto precharge command.

Aspect 14: The method, apparatus, or non-transitory computer-readable medium of any of aspects 1 through 13, further including operations, features, circuitry, logic, means, or instructions, or any combination thereof for enabling the first error correction capability of the memory system based on transmitting the data to the host device.

Aspect 15: The method, apparatus, or non-transitory computer-readable medium of any of aspects 1 through 14, where the first error correction capability includes an on-die ECC.

Aspect 16: The method, apparatus, or non-transitory computer-readable medium of any of aspects 1 through 15, further including operations, features, circuitry, logic, means, or instructions, or any combination thereof for determining that the data read from the one or more memory cells of the memory system at the first time includes the one or more errors of the first type and determining that the data read from the one or more memory cells of the memory system at the second time does not include the one or more errors of the first type.

Aspect 17: The method, apparatus, or non-transitory computer-readable medium of any of aspects 1 through 16, further including operations, features, circuitry, logic, means, or instructions, or any combination thereof for reading, at a fourth time, third data from one or more third memory cells of the memory device; rereading, at a fifth time, the third data from the one or more third memory cells of the memory device; and transmitting an indication to the host device based on determining that the third data includes one or more errors of the first type based on rereading the third data from the one or more third memory cells of the memory system.

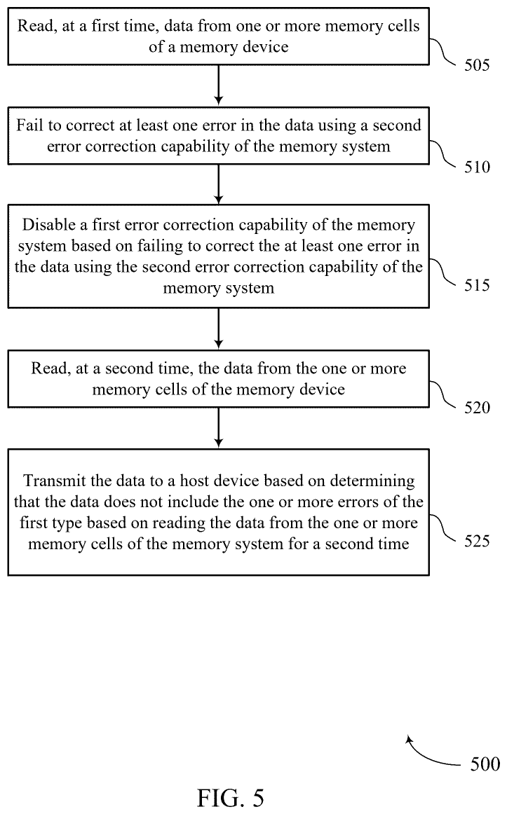

FIG. 5 shows a flowchart illustrating a method 500 that supports error correction disablement by a memory system in accordance with examples as disclosed herein. The operations of method 500 may be implemented by a memory system or its components as described herein. For example, the operations of method 500 may be performed by a memory system as described with reference to FIGS. 1 through 3. In some examples, a memory system may execute a set of instructions to control the functional elements of the device to perform the described functions. Additionally, or alternatively, the memory system may perform aspects of the described functions using special-purpose hardware.

At 505, the method may include reading, at a first time, data from one or more memory cells of a memory device. The operations of 505 may be performed in accordance with examples as disclosed herein. For example, the memory system may include an access component 325 that reads, at the first time, the data from the one or more memory cells of the memory device (e.g., the memory device 145 of FIG. 1).

At 510, the method may include failing to correct at least one error in the data using a second error correction capability of the memory system. The operations of 510 may be performed in accordance with examples as disclosed herein. For example, the memory system may include an error correction component 340 that fails to correct at least one error in the data using the second error correction capability (e.g., the RS circuit 130) of the memory system.

At 515, the method may include disabling a first error correction capability of the memory system based on failing to correct the at least one error in the data using the second error correction capability of the memory system. The operations of 515 may be performed in accordance with examples as disclosed herein. For example, the memory system may include an ECC enablement component 330 that disables a first error correction capability (e.g., ECC circuit 160 of FIG. 1) of the memory system based on failing to correct at least one error in the data using the second error correction capability of the memory system.

At 520, the method may include reading, at a second time, the data from the one or more memory cells of the memory device. The operations of 520 may be performed in accordance with examples as disclosed herein. For example, the memory system may include an access component 325 that reads, at the second time, the data from the one or more memory cells of the memory device (e.g., the memory device 145 of FIG. 1).

At 525, the method may include transmitting the data to a host device based on determining that the data does not include the one or more errors of the first type based on reading the data from the one or more memory cells of the memory system for a second time. The operations of 525 may be performed in accordance with examples as disclosed herein. For example, the memory system may include a communication component 335 that transmits the data to the host device (e.g., the host system 105 of FIG. 1) based on determining that the data does not include the one or more errors of the first type and based on reading the data from the one or more memory cells of the memory system for a second time.

It should be noted that the aspects described herein describe possible implementations, and that the operations and the steps may be rearranged or otherwise modified and that other implementations are possible. Further, portions from two or more of the methods may be combined.

Information and signals described herein may be represented using any of a variety of different technologies and techniques. For example, data, instructions, commands, information, signals, bits, or symbols of signaling that may be referenced throughout the above description may be represented by voltages, currents, electromagnetic waves, magnetic fields or particles, optical fields or particles, or any combination thereof. Some drawings may illustrate signals as a single signal; however, the signal may represent a bus of signals, where the bus may have a variety of bit widths.

A switching component (e.g., a transistor) discussed herein may be a field-effect transistor (FET), and may include a source (e.g., a source terminal), a drain (e.g., a drain terminal), a channel between the source and drain, and a gate (e.g., a gate terminal). A conductivity of the channel may be controlled (e.g., modulated) by applying a voltage to the gate which, in some examples, may result in the channel becoming conductive. A switching component may be an example of an n-type FET or a p-type FET.

The description set forth herein, in connection with the appended drawings, describes example configurations and does not represent all the examples that may be implemented or that are within the scope of the claims. The detailed description includes specific details to provide an understanding of the described techniques. These techniques, however, may be practiced without these specific details. In some instances, well-known structures and devices are shown in block diagram form to avoid obscuring the concepts of the described examples.

In the appended figures, similar components or features may have the same reference label. Similar components may be distinguished by following the reference label by one or more dashes and additional labeling that distinguishes among the similar components. If just the first reference label is used in the specification, the description is applicable to any one of the similar components having the same first reference label irrespective of the additional reference labels.

The functions described herein may be implemented in hardware, software executed by a processing system (e.g., one or more processors, one or more controllers, control circuitry processing circuitry, logic circuitry), firmware, or any combination thereof. If implemented in software executed by a processing system, the functions may be stored on or transmitted over as one or more instructions (e.g., code) on a computer-readable medium. Due to the nature of software, functions described herein can be implemented using software executed by a processing system, hardware, firmware, hardwiring, or combinations of any of these. Features implementing functions may be physically located at various positions, including being distributed such that portions of functions are implemented at different physical locations.

Illustrative blocks and modules described herein may be implemented or performed with one or more processors, such as a DSP, an ASIC, an FPGA, discrete gate logic, discrete transistor logic, discrete hardware components, other programmable logic device, or any combination thereof designed to perform the functions described herein. A processor may be an example of a microprocessor, a controller, a microcontroller, a state machine, or other types of processor. A processor may also be implemented as at least one of one or more computing devices (e.g., a combination of a DSP and a microprocessor, multiple microprocessors, one or more microprocessors in conjunction with a DSP core, or any other such configuration).

As used herein, including in the claims, “or” as used in a list of items (for example, a list of items prefaced by a phrase such as “at least one of” or “one or more of”) indicates an inclusive list such that, for example, a list of at least one of A, B, or C means A or B or C or AB or AC or BC or ABC (i.e., A and B and C). Also, as used herein, the phrase “based on” shall not be construed as a reference to a closed set of conditions. For example, an exemplary step that is described as “based on condition A” may be based on both a condition A and a condition B without departing from the scope of the present disclosure. In other words, as used herein, the phrase “based on” shall be construed in the same manner as the phrase “based at least in part on.”

As used herein, including in the claims, the article “a” before a noun is open-ended and understood to refer to “at least one” of those nouns or “one or more” of those nouns. Thus, the terms “a,” “at least one,” “one or more,” “at least one of one or more” may be interchangeable. For example, if a claim recites “a component” that performs one or more functions, each of the individual functions may be performed by a single component or by any combination of multiple components. Thus, the term “a component” having characteristics or performing functions may refer to “at least one of one or more components” having a particular characteristic or performing a particular function. Subsequent reference to a component introduced with the article “a” using the terms “the” or “said” may refer to any or all of the one or more components. For example, a component introduced with the article “a” may be understood to mean “one or more components,” and referring to “the component” subsequently in the claims may be understood to be equivalent to referring to “at least one of the one or more components.” Similarly, subsequent reference to a component introduced as “one or more components” using the terms “the” or “said” may refer to any or all of the one or more components. For example, referring to “the one or more components” subsequently in the claims may be understood to be equivalent to referring to “at least one of the one or more components.”

Computer-readable media includes both non-transitory computer storage media and communication media including any medium that facilitates transfer of a computer program from one place to another. A non-transitory storage medium may be any available medium, or combination of multiple media, that can be accessed by a computer. By way of example, and not limitation, non-transitory computer-readable media can comprise RAM, ROM, electrically erasable programmable read-only memory (EEPROM), optical disk storage, magnetic disk storage or other magnetic storage devices, or any other non-transitory medium or combination of media that can be used to carry or store desired program code means in the form of instructions or data structures and that can be accessed by a computer, or a processor.

The descriptions and drawings are provided to enable a person having ordinary skill in the art to make or use the disclosure. Various modifications to the disclosure will be apparent to the person having ordinary skill in the art, and the techniques disclosed herein may be applied to other variations without departing from the scope of the disclosure. Thus, the disclosure is not limited to the examples and designs described herein but is to be accorded the broadest scope consistent with the principles and novel features disclosed herein.

What is claimed is:

1. A method by a memory system, comprising:
reading, at a first time, data from one or more memory cells of a memory device;
disabling a first error correction capability of the memory system based on determining that data read from the one or more memory cells of the memory system comprises one or more errors of a first type;
reading, at a second time, the data from the one or more memory cells of the memory device; and
transmitting the data to a host device based on determining that the data does not comprise the one or more errors of the first type based on reading the data from the one or more memory cells of the memory system for the second time.

2. The method of claim 1, wherein determining that the data read from the one or more memory cells of the memory system comprises the one or more errors of the first type comprises:
failing to correct at least one error in the data using a second error correction capability of the memory system.

3. The method of claim 2, wherein the second error correction capability of the memory system comprises a Reed-Solomon error correction code.

4. The method of claim 1, further comprising:
reading, at a third time, second data from one or more second memory cells of the memory system;
correcting the one or more errors in the second data using a second error correction capability of the memory system based on determining that the second data comprises one or more errors of a second type; and
transmitting the second data to the host device based on correcting the one or more errors in the second data using the second error correction capability of the memory system.

5. The method of claim 4, wherein:
the one or more errors of the first type comprise an uncorrectable error (UE); and
the one or more errors of the second type comprise a correctable error (CE).

6. The method of claim 1, further comprising:
reading, at a third time, third data from one or more third memory cells of the memory system;
determining that the third data comprises zero errors based on reading the third data from the one or more third memory cells of the memory system; and
transmitting the third data to the host device based on determining that the third data comprises zero errors.

7. The method of claim 1, further comprising:
determining that the data comprises one or more errors of a second type based on determining that the data does not comprise the one or more errors of the first type; and
correcting the one or more errors of the second type using a second error correction capability of the memory system based on determining that the data comprises the one or more errors of the second type, wherein transmitting the data to the host device is based on correcting the one or more errors of the second type.

8. The method of claim 1, wherein determining that the data does not comprise the one or more errors of the first type comprises:
determining that the data comprises zero errors, wherein transmitting the data to the host device is based on determining that the data comprises zero errors.

9. The method of claim 1, further comprising:
reading a first bit value from a mode register of the memory system, wherein the first bit value indicates that the first error correction capability of the memory system is configured to be disabled, wherein disabling the first error correction capability of the memory system is based on reading the first bit value from the mode register of the memory system.

10. The method of claim 1, further comprising:
receiving, from the host device, a command comprising an indication to write a second bit value to a mode register of the memory system based on determining that the data read from the one or more memory cells of the memory system comprises the one or more errors of the first type; and
writing the second bit value to the mode register of the memory system based on receiving the command, wherein disabling the first error correction capability of the memory system is based on writing the second bit value to the mode register.

11. The method of claim 10, further comprising:
receiving, from the host device, a secret key, wherein writing the second bit value to the mode register of the memory system is based on the secret key.

12. The method of claim 1, further comprising:
receiving, from the host device and based on determining that the data comprises the one or more errors of the first type, a command to reread the data from the one or more memory cells of the memory system, wherein the command comprises an indication to disable the first error correction capability of the memory system.

13. The method of claim 12, wherein the command comprises a write command, a write auto precharge command, a read command, or a read auto precharge command.

14. The method of claim 1, further comprising:
enabling the first error correction capability of the memory system based on transmitting the data to the host device.

15. The method of claim 1, wherein the first error correction capability comprises an on-die error correction code.

16. The method of claim 1, further comprising:
determining that the data read from the one or more memory cells of the memory system at the first time comprises the one or more errors of the first type; and
determining that the data read from the one or more memory cells of the memory system at the second time does not comprise the one or more errors of the first type.

17. The method of claim 1, further comprising:
reading, at a fourth time, third data from one or more third memory cells of the memory device;
rereading, at a fifth time, the third data from the one or more third memory cells of the memory device; and
transmitting an indication to the host device based on determining that the third data comprises one or more errors of the first type based on rereading the third data from the one or more third memory cells of the memory system.

18. A non-transitory computer-readable medium storing code, the code comprising instructions executable by one or more processors to:
read, at a first time, data from one or more memory cells of a memory device;
disable a first error correction capability of a memory system based on determining that the data read from the one or more memory cells of the memory system comprises one or more errors of a first type;
read, at a second time, the data from the one or more memory cells of the memory device; and
transmit the data to a host device based on determining that the data does not comprise the one or more errors of the first type based on reading the data from the one or more memory cells of the memory system for the second time.

19. The non-transitory computer-readable medium of claim 18, wherein the instructions to determine that the data read from the one or more memory cells of the memory system comprises one or more errors of the first type are executable by the one or more processors to:
fail to correct at least one error in the data using a second error correction capability of the memory system.

20. The non-transitory computer-readable medium of claim 18, wherein the instructions are further executable by the one or more processors to:
read, at a third time, second data from one or more second memory cells of the memory system;
correct the one or more errors in the second data using a second error correction capability of the memory system based on determining that the second data comprises one or more errors of a second type; and
transmit the second data to the host device based on correcting the one or more errors in the second data using the second error correction capability of the memory system.

21. The non-transitory computer-readable medium of claim 18, wherein the instructions are further executable by the one or more processors to:
read, at a third time, third data from one or more third memory cells of the memory system;
determine that the third data comprises zero errors based on reading the third data from the one or more third memory cells of the memory system; and
transmit the third data to the host device based on determining that the third data comprises zero errors.

22. The non-transitory computer-readable medium of claim 18, wherein the instructions are further executable by the one or more processors to:
determine that the data comprises one or more errors of a second type based on determining that the data does not comprise the one or more errors of the first type; and
correct the one or more errors of the second type using a second type of error correction capability of the memory system based on determining that the data comprises the one or more errors of the second type, wherein transmitting the data to the host device is based on correcting the one or more errors of the second type.

23. The non-transitory computer-readable medium of claim 18, wherein the instructions to determine that the data does not comprise the one or more errors of the first type are executable by the one or more processors to:
determine that the data comprises zero errors, wherein transmitting the data to the host device is based on determining that the data comprises zero errors.

24. The non-transitory computer-readable medium of claim 18, wherein the instructions are further executable by the one or more processors to:
read a first bit value from a mode register of the memory system, wherein the first bit value indicates that the first error correction capability of the memory system is configured to be disabled, wherein disabling the first error correction capability of the memory system is based on reading the first bit value from the mode register of the memory system.

25. A memory system, comprising:
one or more memory devices; and
processing circuitry coupled with the one or more memory devices and configured to cause the memory system to:
read, at a first time, data from one or more memory cells of a memory device;
disable a first error correction capability of the memory system based on determining that data read from one or more memory cells of the memory system comprises one or more errors of a first type;
read, at a second time, the data from the one or more memory cells of the memory device; and
transmit the data to a host device based on determining that the data does not comprise the one or more errors of the first type based on reading the data from the one or more memory cells of the memory system for the second time.
